(19) United States
(12) Patent Application Publication
(10) Pub. No.: US 2026/0144057 A1
(43) Pub. Date: May 21, 2026

(54) STRUCTURE AND FORMATION METHOD OF PACKAGE WITH HEAT-SPREADING LID

(71) Applicant: Taiwan Semiconductor Manufacturing Company, Ltd., Hsinchu (TW)

(72) Inventors: Chih-Yu CHEN, Miaoli County (TW); Jing-Ruei LU, Taipei City (TW); Cheng-Chi HSIEH, Hsinchu City (TW); Chien-Hsun LEE, Chu-tung Town (TW); Kathy Wei YAN, Hsinchu (TW)

(73) Assignee: Taiwan Semiconductor Manufacturing Company, Ltd., Hsinchu (TW)

(21) Appl. No.: 18/955,104

(22) Filed: Nov. 21, 2024

(51) Int. Cl. H01L 23/367; H01L 23/00; H01L 23/31; H01L 25/065

(52) U.S. Cl. CPC H10W 40/22; H10W 74/114; H10W 74/121; H10W 74/127; H10W 72/283; H10W 90/00; H10W 90/724

(57) ABSTRACT

A package structure and a formation method are provided. The method includes disposing a chip-containing structure over a substrate and forming a protective layer laterally surrounding the chip-containing structure. Interior sidewalls of the protective layer surround an opening exposing a portion of the chip-containing structure. The method also includes forming a thermal interface element in the opening and disposing a heat-spreading lid over the thermal interface element and the protective layer.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature sizes (i.e., the smallest component that can be created using a fabrication process) have decreased. This scaling-down process generally provides benefits by increasing production efficiency and lowering associated costs.

A package structure not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor dies. These relatively new types of packaging technologies for semiconductor dies face manufacturing challenges.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1H are cross-sectional views of various stages of a process for forming a portion of a package structure, in accordance with some embodiments.

FIGS. 2A-2B are cross-sectional views of various stages of a process for forming a portion of a package structure, in accordance with some embodiments.

FIGS. 3A-3B are cross-sectional views of various stages of a process for forming a portion of a package structure, in accordance with some embodiments.

FIG. 4 is a cross-sectional view of a portion of a package structure, in accordance with some embodiments.

FIG. 5 is a top view of a portion of a package structure, in accordance with some embodiments.

FIG. 6 is a cross-sectional view of a portion of a package structure, in accordance with some embodiments.

FIG. 7 is a cross-sectional view of a portion of a package structure, in accordance with some embodiments.

FIG. 8 is a cross-sectional view of a portion of a package structure, in accordance with some embodiments.

FIGS. 9A and 9B are perspective views of portions of a package structure, in accordance with some embodiments.

FIG. 9C is a top view of a portion of a package structure, in accordance with some embodiments.

FIG. 10 is a cross-sectional view of a portion of a package structure, in accordance with some embodiments.

FIG. 11 is a cross-sectional view of a portion of a package structure, in accordance with some embodiments.

FIG. 12 is a cross-sectional view of a portion of a package structure, in accordance with some embodiments.

FIG. 13 is a cross-sectional view of a portion of a package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Embodiments of the disclosure may relate to package structures such as three-dimensional (3D) packaging, 3D-IC devices, and 2.5D packaging. Embodiments of the disclosure form a package structure including a substrate that carries one or more dies or packages and a protective element (such as a protective lid) aside the dies or packages. The protective element may also function as a warpage-control element and/or heat dissipation element.

Other features and processes may also be included. For example, testing structures may be included to aid in the verification testing of the 3D packaging, 3DIC devices, and/or 2.5 D packaging. The testing structures may include, for example, test pads formed in a redistribution layer or on a substrate that allows the testing through probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

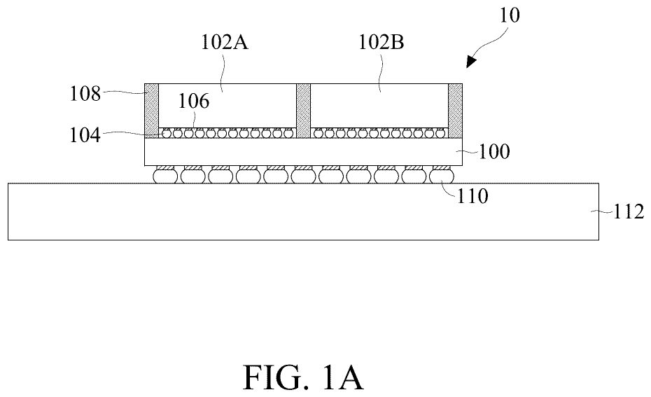

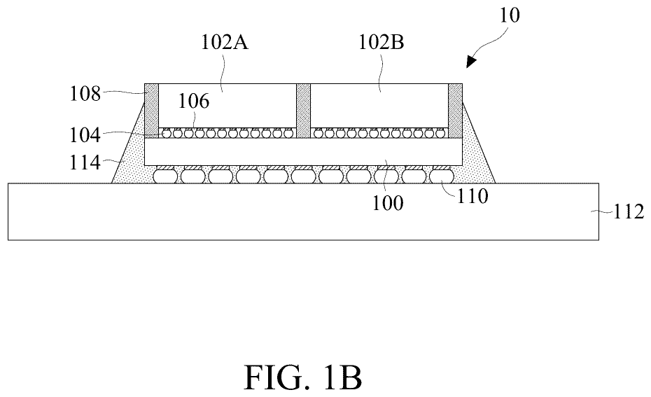

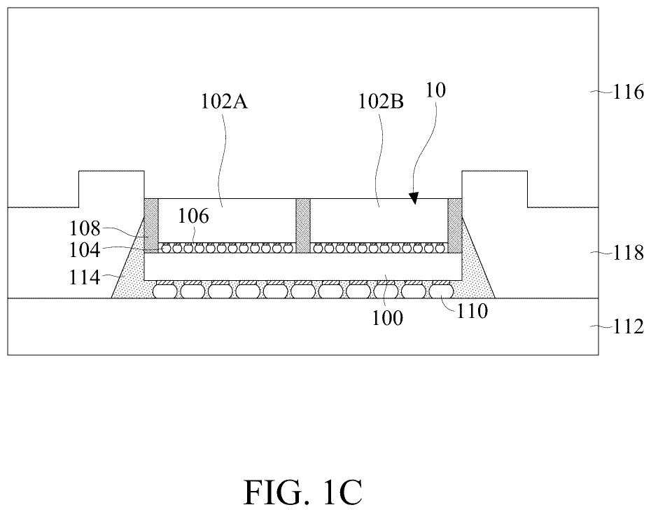

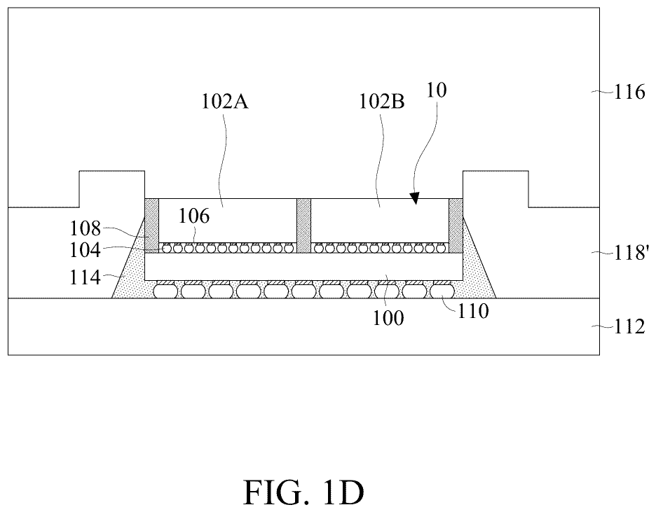

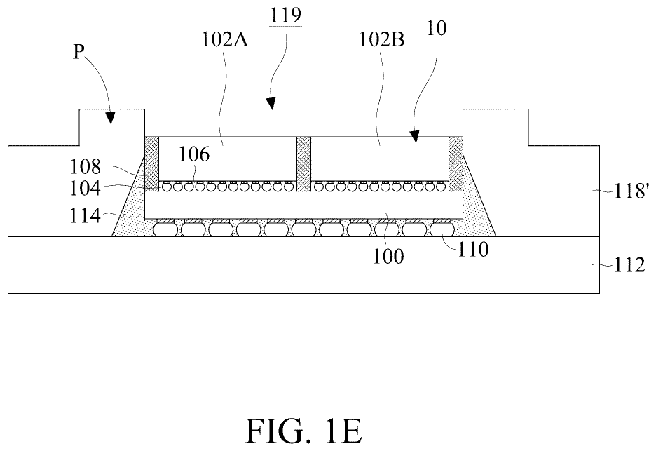

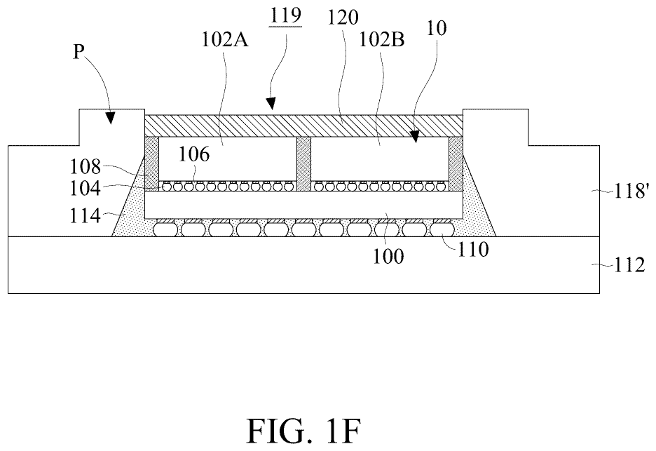

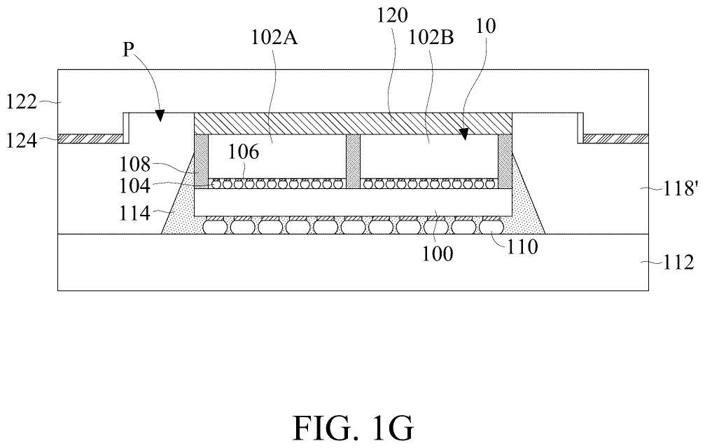

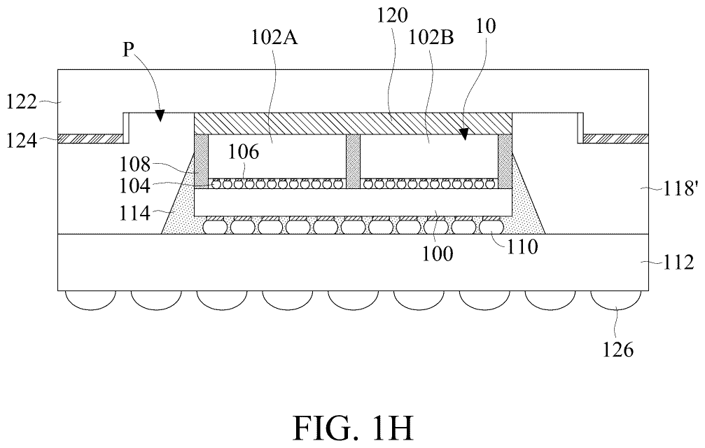

FIGS. 1A-1H are cross-sectional views of various stages of a process for forming a portion of a package structure, in accordance with some embodiments. As shown in FIG. 1A, a chip-containing structure 10 is disposed over a substrate 112, in accordance with some embodiments. In some embodiments, the chip-containing structure 10 is bonded to the substrate 112 through the use of multiple bonding structures 110. The bonding structures 110 may be made of or include solder material. The solder material may be a tin-containing material. The tin-containing material may further include copper, silver, gold, aluminum, lead, one or more other suitable materials, or a combination thereof. In some other embodiments, the solder material is lead-free.

In some embodiments, the chip-containing structure 10 contains multiple semiconductor chips such as semiconductor chips 102A and 102B, as shown in FIG. 1A. Each of the semiconductor chips 102A and 102B may be a single semiconductor die and/or system-on-integrated-chips (SoIC). For the system-on-integrated-chips, multiple semiconductor dies (or chiplets) are stacked and bonded together to form electrical connections between these semiconductor dies. In some embodiments, the semiconductor dies are system-on-chip (SoC) chips that include multiple functions.

In some embodiments, the chip-containing structure 10 includes an interposer substrate 100, as shown in FIG. 1A. In some embodiments, the semiconductor chips 102A and 102B are bonded to the interposer substrate 100 using multiple bonding structures 104. Each of the bonding structures 104 may include a conductive pillar (such as a copper pillar) and a tin-containing solder bump. The tin-containing solder bump may further include copper, silver, gold, aluminum, lead, one or more other suitable materials, or a combination thereof. In some other embodiments, the tin-containing solder bump is lead-free.

In some embodiments, the chip-containing structure 10 includes an underfill structure formed over the interposer substrate 100, so as to laterally surround and protect the bonding structures 104. The underfill structure 106 may be made of or include an epoxy-based resin with fillers dispersed therein. The fillers may include fibers (such as silica fibers and/or carbon-containing fibers), particles (such as silica particles and/or carbon-containing particles), or a combination thereof.

In some embodiments, the chip-containing structure 10 includes a protective layer 108 formed over the interposer substrate 100 to encapsulate and protect the underfill structure 106 and the semiconductor chips 102A and 102B. The protective layer 108 may be made of or include a molding material. The protective layer 108 may be made of or include an epoxy-based resin with fillers dispersed therein. The fillers may include insulating fibers, insulating particles, one or more other suitable elements, or a combination thereof. In some embodiments, the average size of the fillers in the protective layer 108 is larger than that of the fillers in the underfill structure 106. In some embodiments, the weight percentage of the fillers in the protective layer 108 is greater than that of the fillers in the underfill structure 106.

Many variations and/or modifications can be made to embodiments of the disclosure. In some other embodiments, the underfill structure 106 is not formed. The protective layer 108 may further extend into the space between the interposer substrate 100 and the semiconductor chips 102A and 102B to protect the bonding structures 104.

In some embodiments, the interposer substrate 100 is a semiconductor substrate (such as a silicon substrate) that includes multiple through substrate vias (TSVs) formed therein. The through substrate vias may provide electrical connections between the elements (such as the semiconductor chips 102A and 102B) above the interposer substrate 100 and the elements (such as the bonding structures 110) below the interposer substrate 100.

The interposer substrate 100 may further include a front-side interconnection structure and a backside interconnection structure formed on opposite sides of the interposer substrate 100. Each of the front-side interconnection structure and the backside interconnection structure may include multiple dielectric layers and multiple conductive features. The dielectric layers may be made of or include silicon oxide, silicon nitride, silicon oxynitride, carbon-containing silicon oxide, carbon-containing silicon oxynitride, another suitable material, or a combination thereof. The conductive features may include conductive lines, conductive vias, another suitable conductive structure, or a combination thereof.

However, embodiments of the disclosure are not limited thereto. Many variations and/or modifications can be made to embodiments of the disclosure. In some other embodiments, the interposer substrate 100 includes a polymer-based substrate that includes multiple conductive features formed therein. In some other embodiments, the interposer substrate 100 includes a polymer-based substrate and an interconnection chip embedded in or surrounded by the polymer-based substrate.

Many variations and/or modifications can be made to embodiments of the disclosure. In some other embodiments, the chip-containing structure 10 includes only one semiconductor chip. In some other embodiments, the chip-containing structure 10 is a single semiconductor chip.

In some embodiments, a backside metallization layer is formed over the surfaces of the protective layer 108 and the semiconductor chips 102A and 102B. The backside metallization layer may help to improve the adhesion between a subsequently disposed thermal conductive element and the chip-containing structure 10. The backside metallization layer may be made of or include gold, nickel, copper, palladium, another suitable material, or a combination thereof.

However, embodiments of the disclosure are not limited thereto. Many variations and/or modifications can be made to embodiments of the disclosure. In some other embodiments, the backside metallization layer is not formed.

In some embodiments, one or more surface-mounted devices are disposed over the substrate 112. In some embodiments, the surface-mounted devices are bonded to the substrate 112 by bonding structures. Each of the surface-mounted devices is laterally spaced apart from the chip-containing structure 10. Each of the surface-mounted devices may include one or more passive devices such as resistors, capacitors, insulators, another suitable device, or a combination thereof. In some other embodiments, the surface-mounted devices include one or more active devices such as transistor devices, diode devices, another suitable device, or a combination thereof. In some other embodiments, one or more of the surface-mounted devices include a combination of passive devices and active devices.

In some embodiments, the substrate 112 is a circuit board that includes multiple insulating layers and multiple conductive features surrounded by the insulating layers. The conductive features may include conductive lines and conductive vias. Some of the conductive features may be electrically connected to the bonding structures 110 above them.

As shown in FIG. 1B, an underfill structure 114 is formed over the substrate 112 to laterally surround and protect the bonding structures 110, in accordance with some embodiments. A first portion of the underfill structure 114 is between the substrate 112 and the bottom of the chip-containing structure 10. A second portion of the underfill structure 114 may extend upwards along sidewalls of the chip-containing structure 10. The underfill structure 114 may be made of or include an epoxy-based resin with fillers dispersed therein. The fillers may include fibers (such as silica fibers and/or carbon-containing fibers), particles (such as silica particles and/or carbon-containing particles), or a combination thereof.

In some embodiments, an underfill liquid is dispensed onto the substrate 112 along a side of the chip-containing structure 10. The underfill liquid may be made of or include a polymer material, such as an epoxy-based resin with fillers dispersed therein. The fillers may include fibers (such as silica fibers and/or carbon-containing fibers), particles (such as silica particles and/or carbon-containing particles), or a combination thereof. The underfill liquid may be drawn into the space between the substrate 112 and the chip-containing structure 10, so as to surround the bonding structures 110 by the capillary force. Due to the capillary force, the underfill liquid may extend upwards along the sidewalls of the chip-containing structure 10. Afterwards, a thermal operation may be used to cure the underfill liquid. As a result, the underfill liquid is turned into the underfill structure 114.

As shown in FIG. 1C, a mold 116 is disposed to partially or completely cover the top surface of the chip-containing structure, in accordance with some embodiments. The mold 116 may function as a blocking element that assists in a subsequent formation of a protective layer. In some embodiments, the mold 116 extends across opposite edges of the chip-containing structure 10. In some embodiments, the mold 116 is also placed on the substrate 112 and occupies edge areas of the substrate 112.

Afterwards, a molding liquid is introduced into the space between the mold 116 and the substrate 112, in accordance with some embodiments. The molding liquid is constrained by the mold, forming a molding material 118 that laterally surrounds the chip-containing structure 10.

Afterwards, a thermal operation may be used to cure the molding material 118. As a result, the molding material 118 is cured to form a protective layer 118′, as shown in FIG. 1D in accordance with some embodiments. The protective layer 118′ may be made of or include a polymer material, such as an epoxy-based resin with fillers dispersed therein. The epoxy-based resin may include multi-aromatic epoxy resin, biphenyl epoxy resin, another suitable material, or a combination thereof. The fillers may include fibers (such as silica fibers and/or carbon-containing fibers), particles (such as silica particles and/or carbon-containing particles), or a combination thereof. The weight percentage of the fillers may be in a range from about 80% to about 90%.

As shown in FIG. 1E, the mold 116 is removed, in accordance with some embodiments. The top surfaces of the protective layer 118′ and the chip-containing structure 10 are exposed. In some embodiments, the protective layer 118′ has a protruding portion P, as shown in FIG. 1E. The protruding portion P may extend beyond the top surface of the chip-containing structure 10.

In some embodiments, interior sidewalls of the protruding portion P laterally surrounds an opening (or a cavity) 119 that exposes a portion of the chip-containing structure 10. In some embodiments, the protruding portion P continuously surround the opening 119 that partially or completely expose the top surface of the chip-containing structure 10.

As shown in FIG. 1F, a thermal interface element 120 is formed in the opening 119, in accordance with some embodiments. In some embodiments, the thermal interface element 120 is made of or include a metal material. In some embodiments, the thermal interface element 120 is made of or include a metal material that has a low melting point and has a low stress. Thermal interface element 120 may be an indium-based material, a gallium-based material, another suitable material, or a combination thereof.

In some embodiments, a solid thermally conductive element is used as the thermal interface element 120. The solid thermally conductive element may be picked and placed in the opening 119. The solid thermally conductive element may be made of or include indium, an alloy of indium and silver, an alloy of indium and tin, another suitable material, or a combination thereof. In some embodiments, a liquid thermally conductive element is dispensed into the opening 119 to form the thermal interface element 120. The liquid thermally conductive element may be made of or include gallium, an alloy of gallium and indium, an alloy of gallium, indium and tin, an alloy of gallium, indium, tin and zinc, another suitable material, or a combination thereof.

In some embodiments, the entirety of the thermal interface element 120 is positioned within the opening 119. In some other embodiments, an upper portion of the thermal interface element 120 extends out from the opening 119.

As shown in FIG. 1G, a heat-spreading lid 122 is disposed over the thermal interface element 120, in accordance with some embodiments. In some embodiments, the heat-spreading lid 122 is attached to the protective layer 118′ via an adhesive layer 124. In some embodiments, the heat-spreading lid 122 is pressed against the thermal interface element 120 and the adhesive layer 124 at an elevated temperature. The elevated temperature may be within a range from about 130 degrees C to about 200 degrees C. The operating time may be in a range from about 10 minutes to about 2 hours. After the thermal operation, the heat-spreading lid 122 may be bonded to the thermal interface element 120. In some embodiments, even if the thermal interface element 120 extends out from the opening 119, the thermal interface element 120 may be pressed into the opening 119 after the heat-spreading lid 122 is disposed.

In some embodiments, the heat-spreading lid 122 is a thermally conductive lid. The heat-spreading lid 122 may be made of or include copper, aluminum, steel, titanium, nickel, gold, silver, another suitable material, or a combination thereof. In some embodiments, the heat-spreading lid 122 has a main body that is made of or include copper. The heat-spreading lid 122 may further have one or more other layers coated on the main body. For example, these layers may include an inner layer made of nickel and one or more outer layers that are made of gold and/or silver. The heat-spreading lid 122 may also function as a stiffener of the package structure.

In some embodiments, the heat-spreading lid 122 is in direct contact with the protective layer 118′ and the thermal interface element 120. The heat-spreading lid 122 and the protective layer 118′ work together to contain the thermal interface element 120, preventing any melted portion and/or any pressed portion of the thermal interface element 120 from reaching components like the surface-mounted devices on the substrate 112. The risk of short-circuiting the surface-mounted devices is greatly minimized.

As shown in FIG. 1H, multiple bonding structures 126 are formed below the substrate 112, in accordance with some embodiments. In some embodiments, each of the bonding structures 126 is wider than each of the bonding structures 110 or 104. In some embodiments, each of the bonding structures 126 is larger than each of the bonding structures 110 or 104. In some embodiments, the pitch between the bonding structures 126 is larger than the pitch between the bonding structures 110 or 104.

The bonding structures 126 may include tin-containing solder bumps. The tin-containing solder bump may further include copper, silver, gold, aluminum, lead, one or more other suitable materials, or a combination thereof. In some other embodiments, the tin-containing solder bump is lead-free.

The formation of the bonding structures 126 may involve a thermal reflow process. During the thermal reflow process, the thermal interface element 120 may be partially melt. The heat-spreading lid 122 and the protective layer 118′ laterally surrounding the thermal interface element 120 may work together to contain the thermal interface element 120, preventing any melted portion from leaking or flowing into other areas. The heat dissipation of the chip-containing structure 10 is thus ensured. Other elements like surface-mounted devices on the substrate 112 are also protected. The reliability and performance of the package structure are greatly improved.

In some embodiments, the protective layer 118′ does not cover the top surface of the chip-containing structure 10, as shown in FIG. 1H. However, embodiments of the disclosure are not limited thereto. Many variations and/or modifications can be made to embodiments of the disclosure. In some other embodiments, the protective layer 118′ partially covers the top surface of the chip-containing structure 10.

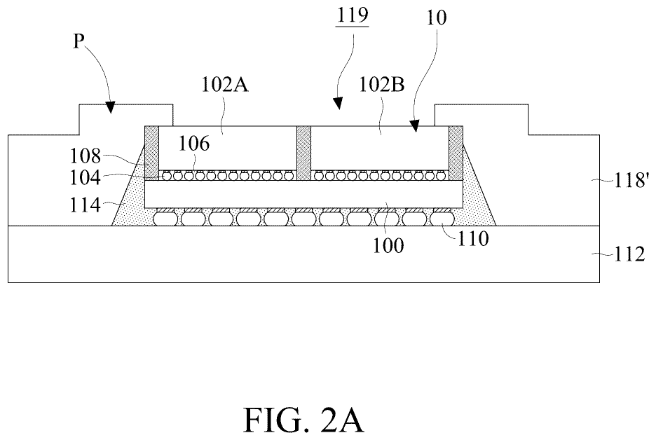

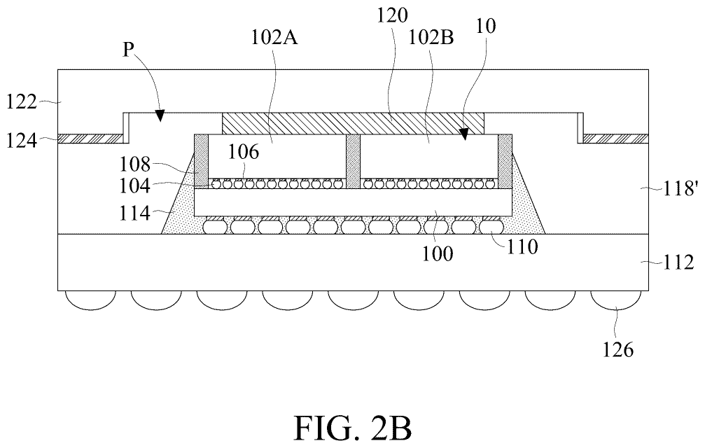

FIGS. 2A-2B are cross-sectional views of various stages of a process for forming a portion of a package structure, in accordance with some embodiments. As shown in FIG. 2A, a structure that is similar to the structure shown in FIG. 1E is formed. In some embodiments, the protruding portion P of the protective layer 118′ covers the edge portions of the chip-containing structure 10. In some embodiments, the protective layer 118′ partially covers the protective layer 108 of the chip-containing structure 10. In some embodiments, the protective layer 118′ partially covers the semiconductor chips 102A and 102B of the chip-containing structure 10.

Afterwards, the processes that are the same as or similar to those illustrated in FIGS. 1F-1H are performed. As a result, the structure shown in FIG. 2B is formed. In some embodiments, the protective layer 118′ is in direct contact with the thermal interface element 120 and the semiconductor chips 102A and 102B.

In some embodiments, the protective layer 118′ defines a single opening (i.e., the opening 119) that exposes the chip-containing structure 10. However, embodiments of the disclosure are not limited thereto. Many variations and/or modifications can be made to embodiments of the disclosure. In some other embodiments, the protective layer 118′ surrounds two or more openings that partially expose the top surface of the chip-containing structure 10.

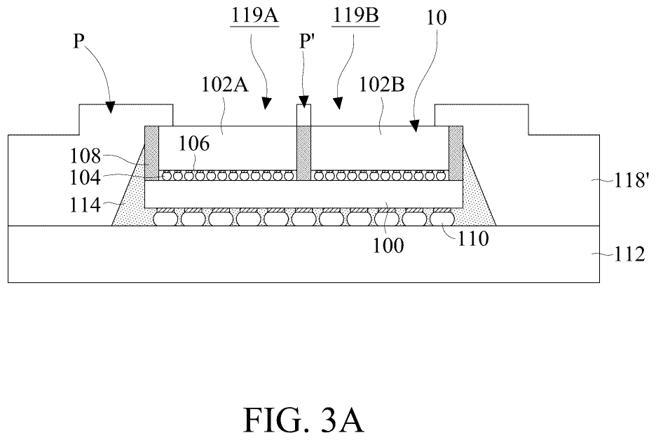

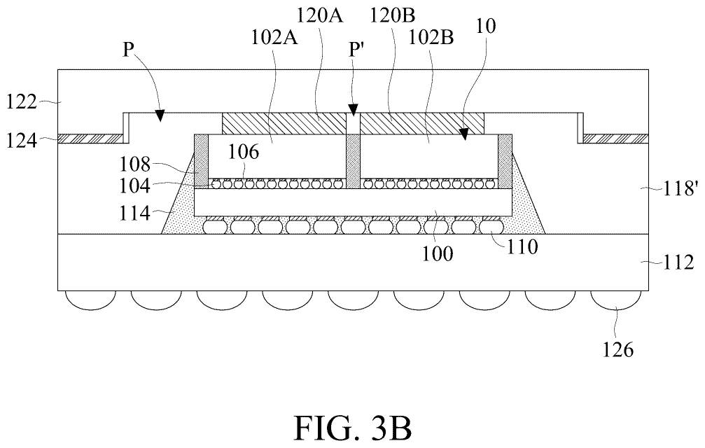

FIGS. 3A-3B are cross-sectional views of various stages of a process for forming a portion of a package structure, in accordance with some embodiments. As shown in FIG. 3A, a structure that is similar to the structure shown in FIG. 1E is formed. In some embodiments, similar to the embodiments shown in FIGS. 2A and 2B, the protruding portion P of the protective layer 118′ covers the edge portions of the chip-containing structure 10. In some embodiments, the protective layer 118′ partially covers the protective layer 108 of the chip-containing structure 10. In some embodiments, the protective layer 118′ partially covers the semiconductor chips 102A and 102B of the chip-containing structure 10.

In some embodiments, the protective layer 118′ further includes a second protruding portion P'. In some embodiments, the second protruding portion P′ covers the portion of the protective layer 108 that is between the semiconductor chips 102A and 102B. In some embodiments, the protruding portion P and the second protruding portion P′ together surround openings 119A and 119B, as shown in FIG. 3A. The openings 119A and 119B partially expose the top surfaces of the semiconductor chips 102A and 102B, respectively.

Afterwards, the processes that are the same as or similar to those illustrated in FIGS. 1F-1H are performed. As a result, the structure shown in FIG. 3B is formed. In some embodiments, thermal interface elements 120A and 120B are formed. In some embodiments, the thermal interface elements 120A and 120B are made of the same material. In some other embodiments, the thermal interface elements 120A and 120B are made of different materials. In some embodiments, the semiconductor chips 102A and 102B have different operation temperatures. The thermal interface elements 120A and 120B, made from different materials or compositions, may be used to accommodate the semiconductor chips 102A and 102B with different operation temperatures.

In some embodiments, the heat-spreading lid 122 is attached to the protective layer 118′ by the adhesive layer 124. However, embodiments of the disclosure are not limited thereto. Many variations and/or modifications can be made to embodiments of the disclosure. In some other embodiments, a heat-spreading lid is attached to the substrate 112 using an adhesive layer.

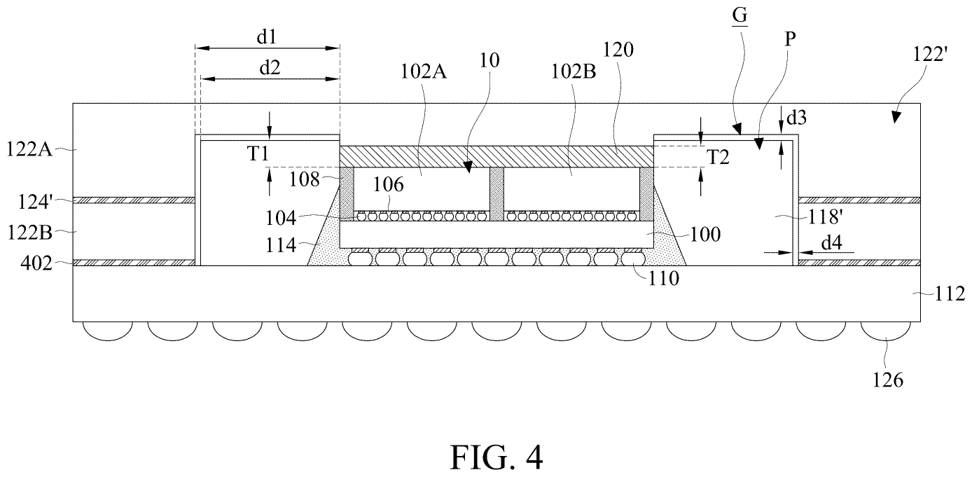

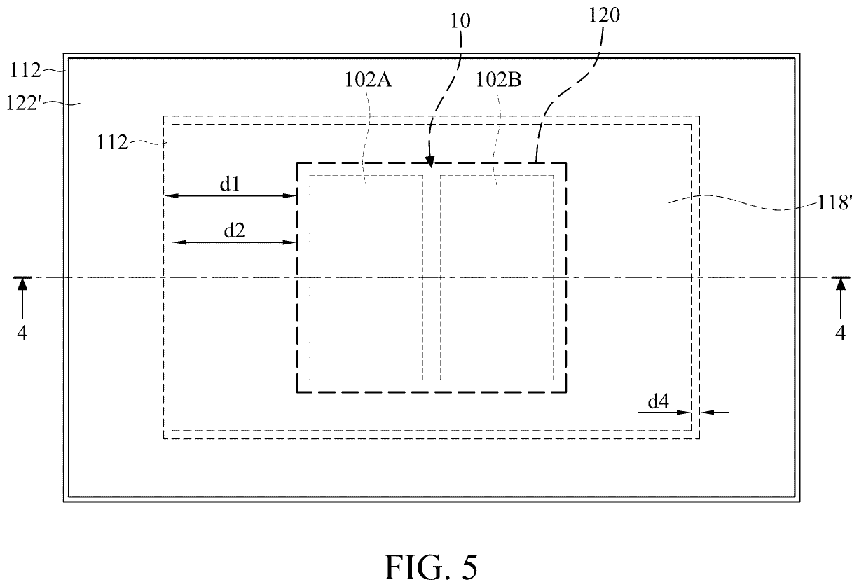

FIG. 4 is a cross-sectional view of a portion of a package structure, in accordance with some embodiments. FIG. 5 is a top view of a portion of a package structure, in accordance with some embodiments. In some embodiments, FIG. 4 is a cross-sectional view of the package structure taken along the line 4-4 in FIG. 5.

As shown in FIG. 4, a heat-spreading lid 122′ is attached to the substrate 112 by an adhesive layer 402, in accordance with some embodiments. In some embodiments, the heat-spreading lid 122′ is pressed against the thermal interface element 120. In some embodiments, the protective layer 118′ extends upwards along the sidewall of the thermal interface element 120, surpassing the interface between the thermal interface element 120 and the heat-spreading lid 122′.

In some embodiments, the heat-spreading lid 122′ includes an upper portion 122A and a lower ring portion 122B. The upper portion 122A may be attached to the lower ring portion 122B via an adhesive layer 124′. In some embodiments, the upper portion 122A and the lower ring portion 122B are made of the same material. In some other embodiments, the upper portion 122A and the lower ring portion 122B are made of different materials. The upper portion 122A and the lower ring portion 122B may be made of or include copper, aluminum, steel, titanium, nickel, gold, silver, another suitable material, or a combination thereof.

In some embodiments, the heat-spreading lid 122′ continuously surrounds the protective layer 118′, the thermal interface element 120, and the semiconductor chips 102A and 102B of the chip-containing structure 10, as shown in FIGS. 4 and 5. In some embodiments, the heat-spreading lid 122′ and the protective layer 118′ together surround a gap G, as shown in FIG. 4. In some embodiments, the outermost edges of the protective layer 118′ are separated from the heat-spreading lid 122′ by the gap G.

As shown in FIGS. 4 and 5, the interior sidewall of the heat-spreading lid 122′ is separated from the edge of the chip-containing structure 10 (i.e., also the edge of the thermal interface element 120 in some embodiments) by a distance d1. As shown in FIGS. 4 and 5, the sidewall of the protective layer 118′ is separated from the edge of the chip-containing structure 10 (i.e., also the edge of the thermal interface element 120 in some embodiments) by a distance d2. In some embodiments, the distance d1 is slightly larger than the distance d2. The distance d2 may be in a range from about 1000 μm to about 600000 μm.

As shown in FIG. 4, the protruding portion P that extends beyond the top surface of the chip-containing structure 10 has a thickness T1. The thermal interface element 120 has a thickness T2. In some embodiments, the thickness T1 is larger than the thickness T2. In some embodiments, the thickness T1 is substantially equal to the thickness T2. The thickness T 1 of the protruding portion P may be in a range from about 10 μm to about 1000 μm. The thickness T2 of the thermal interface element 120 may be in a range from about 10 μm to about 1100 μm.

As shown in FIG. 4, the gap G creates a separation. The top of the protective layer 118′ is distanced from the heat-spreading lid 122′ by a distance d3. The distance d3 may be in a range from about 1 μm to about 3000 μm.

However, embodiments of the disclosure are not limited thereto. Many variations and/or modifications can be made to embodiments of the disclosure. In some other embodiments, the top of the protective layer 118′ is in direct contact with the heat-spreading lid 122′.

As shown in FIGS. 4 and 5, the sidewall of the protective layer 118′ is distanced from the heat-spreading lid 122′ by a distance d4. The distance d4 may be in a range from about 1 μm to about 5000 μm.

However, embodiments of the disclosure are not limited thereto. Many variations and/or modifications can be made to embodiments of the disclosure. In some other embodiments, the sidewall of the protective layer 118′ is in direct contact with the heat-spreading lid 122′.

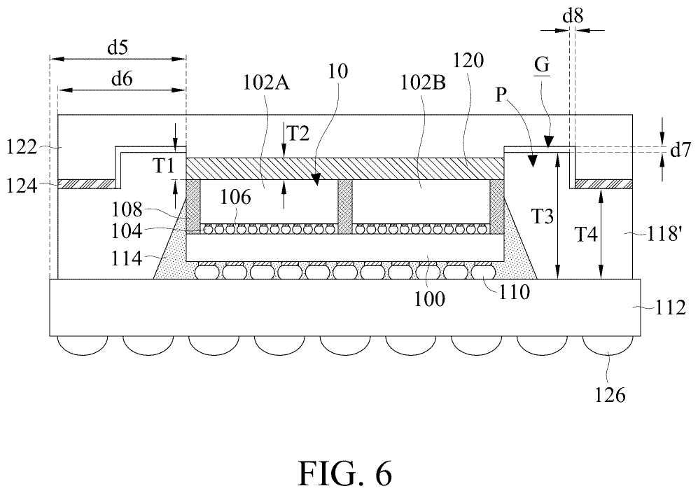

Many variations and/or modifications can be made to embodiments of the disclosure. FIG. 6 is a cross-sectional view of a portion of a package structure, in accordance with some embodiments. In some embodiments, the heat-spreading lid 122 is attached to the protective layer 118′ by the adhesive layer 124. As shown in FIG. 6, the heat-spreading lid 122 and the protective layer 118′ together surround a gap G. In some embodiments, the gap G is a closed gap. In some embodiments, the protective layer 118′ has the protruding portion P that extends upwards along the sidewall of the thermal interface element 120, surpassing the interface between the thermal interface element 120 and the heat-spreading lid 122.

As shown in FIG. 6, the edge of the substrate 112 is laterally separated from the edge of the chip-containing structure 10 by a distance d5. As shown in FIG. 6, the sidewall of the protective layer 118′ is separated from the edge of the chip-containing structure 10 by a distance d6. In some embodiments, the distance d5 is larger than the distance d6. The distance d6 may be in a range from about 1000 μm to about 600000 μm.

As shown in FIG. 6, the top of the protruding portion P is distanced from the heat-spreading lid 122 by a distance d7, and the outer edge of the protruding portion P is distanced from the heat-spreading lid 122 by a distance d8. The distance d7 may be in a range from about 1 μm to about 3000 μm. The distance d8 may be in a range from about 1 μm to about 5000 μm.

However, embodiments of the disclosure are not limited thereto. Many variations and/or modifications can be made to embodiments of the disclosure. In some other embodiments, the heat-spreading lid 122′ is in direct contact with the top and/or the outer edge of the protruding portion P.

As shown in FIG. 6, the protective layer 118′ has an inner portion beside the chip-containing structure 10 and an outer portion below the adhesive layer 124. The inner portion has a thickness T3, and the outer portion has a thickness T4. In some embodiments, the thickness T3 is greater than the thickness T4. The thickness T3 is, for example, greater than about 100 μm.

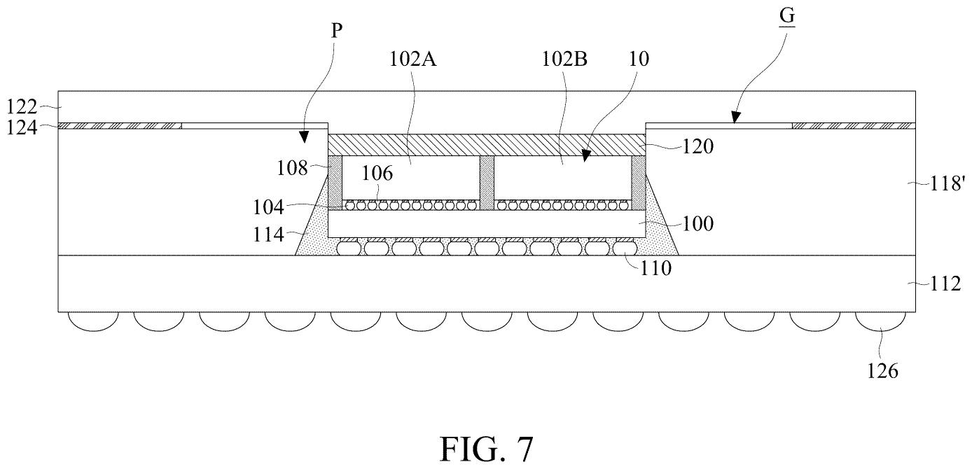

Many variations and/or modifications can be made to embodiments of the disclosure. FIG. 7 is a cross-sectional view of a portion of a package structure, in accordance with some embodiments. A structure that is similar to that shown in FIG. 6 is formed. In some embodiments, the inner portion beside the chip-containing structure 10 is substantially as thick as the outer portion below the adhesive layer 124.

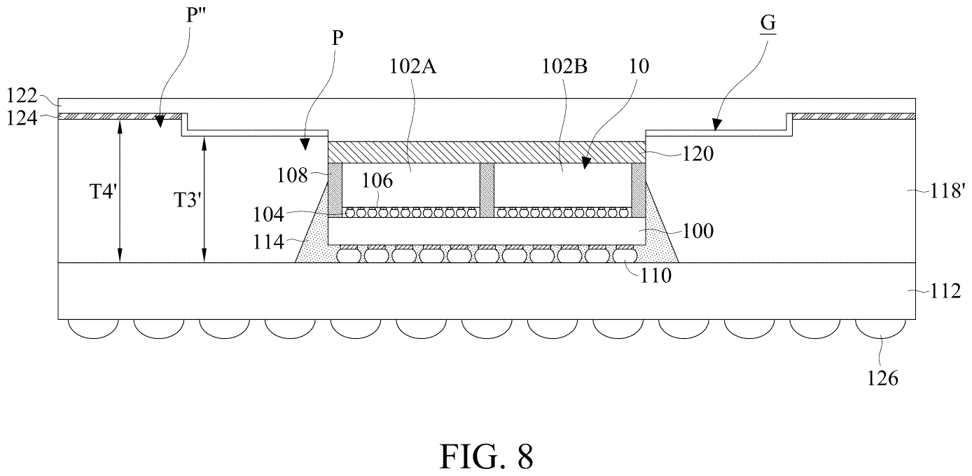

Many variations and/or modifications can be made to embodiments of the disclosure. FIG. 8 is a cross-sectional view of a portion of a package structure, in accordance with some embodiments. A structure that is similar to that shown in FIG. 6 is formed. As shown in FIG. 8, the protective layer 118′ has an inner portion beside the chip-containing structure 10 and an outer portion below the adhesive layer 124. The inner portion has a thickness T3′, and the outer portion has a thickness T4′. In some embodiments, the thickness T4′ is greater than the thickness T3′. The thickness T3′ is, for example, greater than about 100 μm. In some embodiments, the protruding portion P laterally surrounds the thermal interface element 120. In some embodiments, the protective layer 118′ further include a second protruding portion P″ extending upwards beyond the protruding portion P, as shown in FIG. 8.

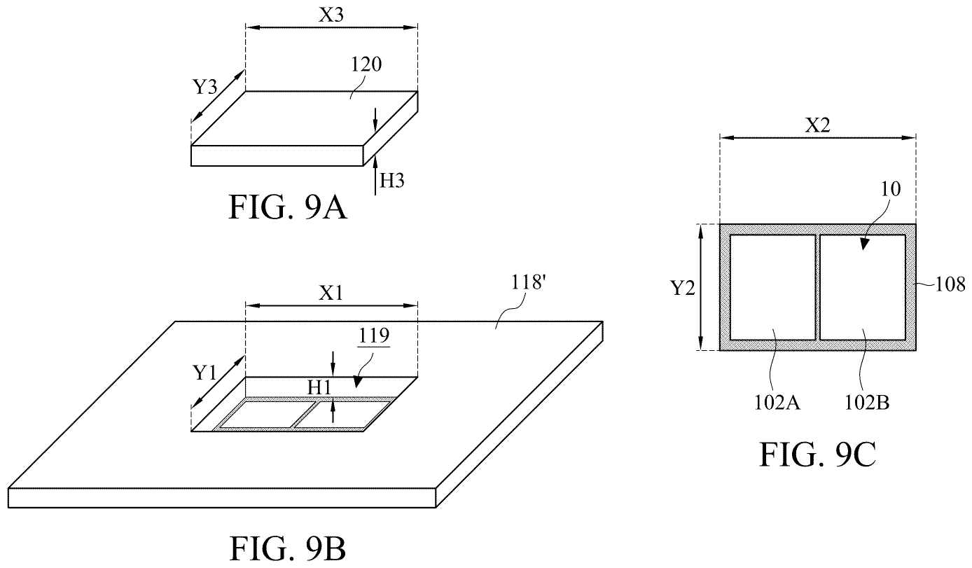

Many variations and/or modifications can be made to embodiments of the disclosure. FIGS. 9A and 9B are perspective views of portions of a package structure, in accordance with some embodiments. FIG. 9C is a top view of a portion of a package structure, in accordance with some embodiments. In some embodiments, FIGS. 9A-9C show portions of the package structure shown in FIGS. 1F, 1H, 2B, 3B, 4, 5, 6, 7, and 8.

In some embodiments, FIG. 9A shows a perspective view of the thermal interface element 120. As shown in FIG. 9A, the thermal interface element 120 has a width X3 measured in one direction and a second width Y3 measured in a perpendicular direction. The thermal interface element 120 also has a height H3. The height H3 may be in a range from about 10 μm to about 1100 μm.

In some embodiments, FIG. 9B shows a perspective view of a portion of the protective layer 118′. As shown in FIG. 9B, the protective layer 118′ has interior sidewalls that surround the opening 119. The opening 119 has a width X1 measured in one direction and a second width Y1 measured in a perpendicular direction. The opening 119 also has a depth H1, as shown in FIG. 9B. The depth H1 may be in a range from about 10 μm to about 1000 μm.

In some embodiments, FIG. 9C shows the top view of the chip-containing structure 10. As shown in FIG. 9C, the chip-containing structure 10 has a width X2 measured in one direction and a second width Y2 measured in a perpendicular direction.

In some embodiments, the width X1 is in a range from about 0.5 times the width X2 to about 1.5 times the width X2. In some embodiments, the width Y1 is in a range from about 0.5 times the width Y2 to about 1.5 times the width Y2. In some embodiments, the width X3 is in a range from about 0.5 times the width X1 to about one time the width X1. In some embodiments, the width Y3 is in a range from about 0.5 times the width Y1 to about one time the width Y1.

In some embodiments, one or more gaps are formed between the heat-spreading lid and the protective layer. The entirety of the thermal interface element is contained in the opening surrounded by the protective layer and the heat-spreading element. However, embodiments of the disclosure are not limited thereto. Many variations and/or modifications can be made to embodiments of the disclosure. In some other embodiments, a portion of the thermal interface element is pressed into the gap.

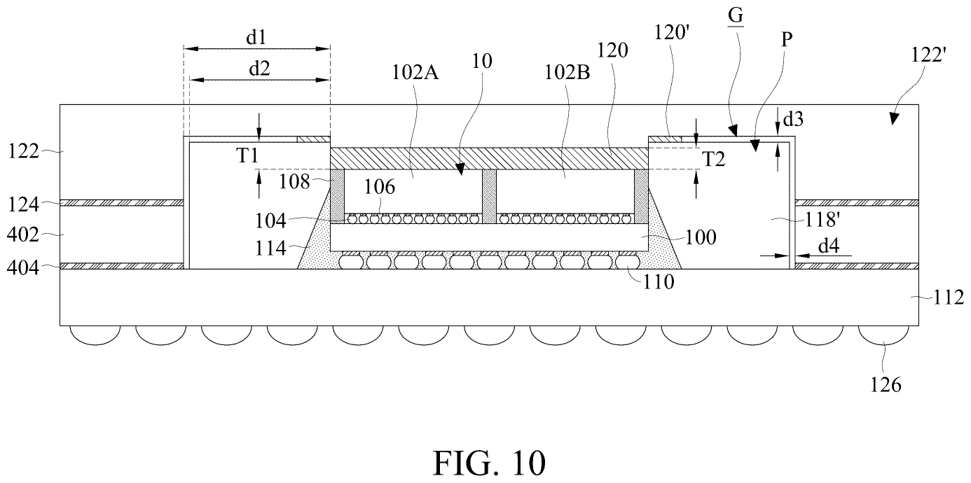

FIG. 10 is a cross-sectional view of a portion of a package structure, in accordance with some embodiments. In some embodiments, a package structure that is similar to that shown in FIG. 4 is formed. In some embodiments, a portion of the thermal interface element 120 is pressed into the gap G while pressing the heat-spreading lid 122′ against the thermal interface element 120. As a result, thermal interface elements 120′ are formed in the gap G, as shown in FIG. 10.

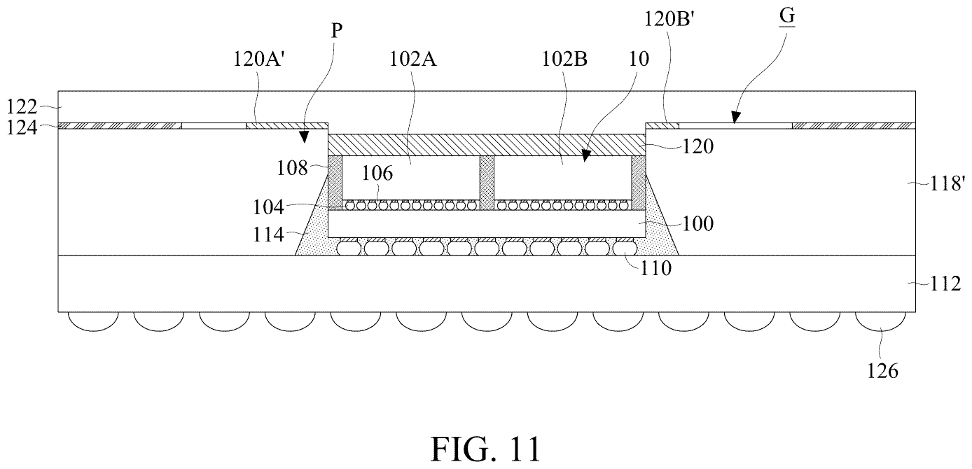

Many variations and/or modifications can be made to embodiments of the disclosure. FIG. 11 is a cross-sectional view of a portion of a package structure, in accordance with some embodiments. In some embodiments, a package structure that is similar to that shown in FIG. 7 is formed. In some embodiments, a portion of the thermal interface element 120 is pressed into the gap G while pressing the heat-spreading lid 122 against the thermal interface element 120. As a result, thermal interface elements 120A′ and 120B′ are formed in the gap G, as shown in FIG. 11. In some embodiments, the thermal interface elements 120A′ is wider than the thermal interface elements 120B′. In some other embodiments, the thermal interface elements 120A′ is substantially as wide as the thermal interface elements 120B′.

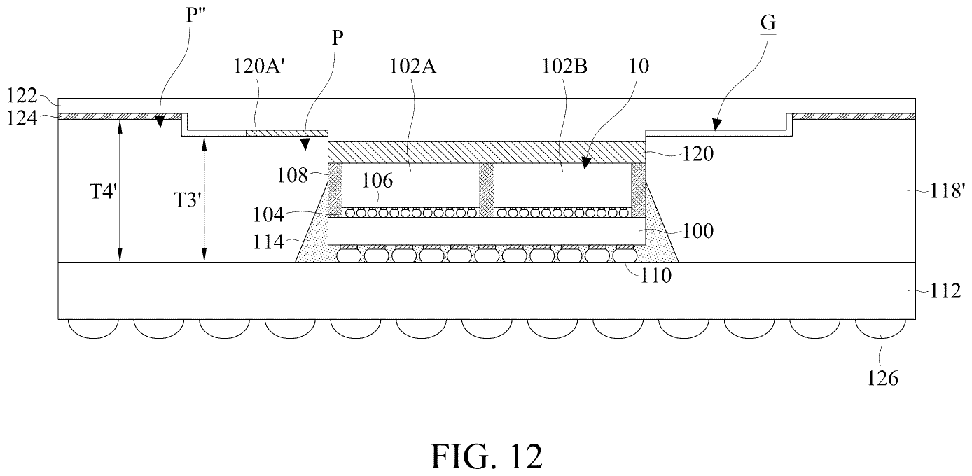

Many variations and/or modifications can be made to embodiments of the disclosure. FIG. 12 is a cross-sectional view of a portion of a package structure, in accordance with some embodiments. In some embodiments, a package structure that is similar to that shown in FIG. 8 is formed. In some embodiments, a portion of the thermal interface element 120 is pressed into the gap G while pressing the heat-spreading lid 122 against the thermal interface element 120. As a result, a thermal interface element 120A′ is formed in the gap G, as shown in FIG. 12.

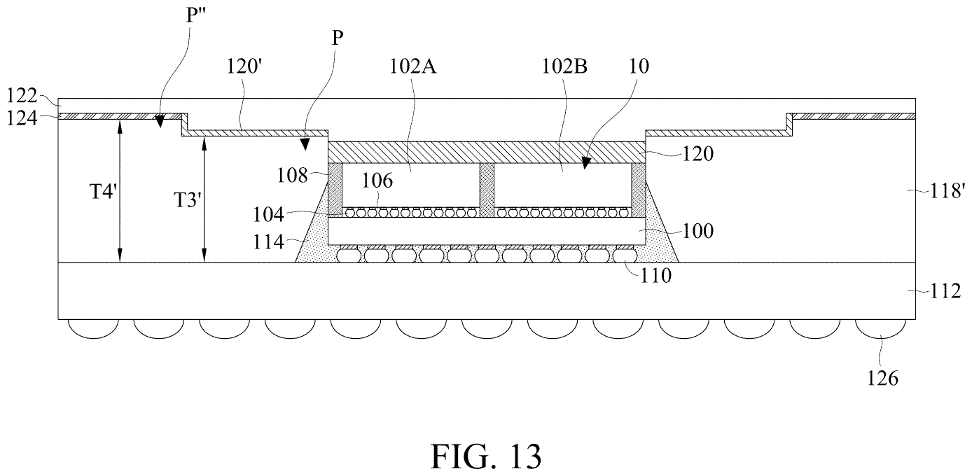

Many variations and/or modifications can be made to embodiments of the disclosure. FIG. 13 is a cross-sectional view of a portion of a package structure, in accordance with some embodiments. In some embodiments, a package structure that is similar to that shown in FIG. 8 is formed. In some embodiments, a portion of the thermal interface element 120 is pressed into the gap G while pressing the heat-spreading lid 122 against the thermal interface element 120. As a result, a thermal interface element 120A′ is formed in the gap G, as shown in FIG. 13. In some embodiments, the thermal interface element 120A′ completely fills the gap G.

In some embodiments, even if a portion of the thermal interface element 120 is pressed into the gap G, the substrate 112 remained covered and protected by the protective layer 118′. The components like surface-mounted devices on the substrate 112 is prevented from being reached by the thermal interface element 120. The risk of short-circuiting the surface-mounted devices is greatly minimized.

Embodiments of the disclosure form a package structure with a heat-spreading lid. A chip-containing structures is placed between the heat-spreading lid and a substrate. A protective layer is formed laterally surrounding the chip-containing structure and a thermal interface element between the chip-containing structure and the heat-spreading lid. Any melted portion and/or pressed portion of the thermal interface element is prevented from leaking or flowing into other areas. The heat dissipation of the chip-containing structure is thus ensured. Other elements like surface-mounted devices on the substrate are also protected. The reliability and performance of the package structure are significantly improved.

In accordance with some embodiments, a method for forming a package structure is provided. The method includes disposing a chip-containing structure over a substrate and forming a protective layer laterally surrounding the chip-containing structure. Interior sidewalls of the protective layer surround an opening exposing a portion of the chip-containing structure. The method also includes forming a thermal interface element in the opening and disposing a heat-spreading lid over the thermal interface element and the protective layer.

In accordance with some embodiments, a method for forming a package structure is provided. The method includes bonding a chip-containing structure to a substrate and forming a protective layer laterally surrounding the chip-containing structure. The protective layer has a protruding portion continuously surrounding an opening exposing the chip-containing structure. The method also includes forming a thermal interface element in the opening and bonding a heat-spreading lid to the thermal interface element.

In accordance with some embodiments, a package structure is provided. The package structure includes a chip-containing structure bonded to a substrate and a thermal interface element over the chip-containing structure. The package structure also includes a protective layer laterally surrounding the thermal interface element and the chip-containing structure. The package structure further includes a heat-spreading lid bonded to the thermal interface element.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a package structure, comprising:
disposing a chip-containing structure over a substrate;
forming a protective layer laterally surrounding the chip-containing structure, wherein interior sidewalls of the protective layer surround an opening exposing a portion of the chip-containing structure;
forming a thermal interface element in the opening; and
disposing a heat-spreading lid over the thermal interface element and the protective layer.

2. The method for forming a package structure as claimed in claim 1, wherein the heat-spreading lid is in direct contact with the thermal interface element.

3. The method for forming a package structure as claimed in claim 1, wherein the heat-spreading lid is in direct contact with the protective layer.

4. The method for forming a package structure as claimed in claim 1, further comprising:
attaching the heat-spreading lid to the protective layer by an adhesive layer.

5. The method for forming a package structure as claimed in claim 1, further comprising:
attaching the heat-spreading lid to the substrate by an adhesive layer.

6. The method for forming a package structure as claimed in claim 1, wherein the formation of the thermal interface element comprises placing a solid thermally conductive element in the opening, dispensing a liquid thermally conductive material in the opening, or a combination thereof.

7. The method for forming a package structure as claimed in claim 1, further comprising:
placing a mold over the chip-containing structure and the substrate;
injecting a molding material between the mold and the substrate, wherein the molding material laterally surrounds the chip-containing structure; and
curing the molding material to transform the molding material into the protective layer.

8. The method for forming a package structure as claimed in claim 1, wherein the protective layer partially covers a top surface of the chip-containing structure.

9. The method for forming a package structure as claimed in claim 1, wherein a gap is formed between the heat-spreading lid and the protective layer after the heat-spreading lid is disposed.

10. The method for forming a package structure as claimed in claim 1, wherein a portion of the thermal interface element is pressed into the gap to at least partially fill the gap after the heat-spreading lid is disposed.

11. A method for forming a package structure, comprising:
bonding a chip-containing structure to a substrate;
forming a protective layer laterally surrounding the chip-containing structure, wherein the protective layer has a protruding portion continuously surrounding an opening exposing the chip-containing structure;
forming a thermal interface element in the opening; and
bonding a heat-spreading lid to the thermal interface element.

12. The method for forming a package structure as claimed in claim 11, further comprising:
attaching the heat-spreading lid to the protective layer.

13. The method for forming a package structure as claimed in claim 11, further comprising:
attaching the heat-spreading lid to the substrate.

14. The method for forming a package structure as claimed in claim 11, wherein the heat-spreading lid extends across opposite edges of the protective layer.

15. The method for forming a package structure as claimed in claim 11, further comprising:
disposing a blocking element to at least partially cover a top surface of the chip-containing structure;
forming the protective layer laterally surrounding the chip-containing structure and at least partially surrounding the blocking element; and
removing the blocking element before the thermal interface element is formed.

16. A package structure, comprising:
a chip-containing structure bonded to a substrate;
a thermal interface element over the chip-containing structure;
a protective layer laterally surrounding the thermal interface element and the chip-containing structure; and
a heat-spreading lid bonded to the thermal interface element.

17. The package structure as claimed in claim 16, wherein the protective layer extends upwards along a sidewall of the thermal interface element, surpassing an interface between the thermal interface element and the heat-spreading lid.

18. The package structure as claimed in claim 16, wherein the heat-spreading lid and the protective layer together surround a gap.

19. The package structure as claimed in claim 16, further comprising:
an adhesive layer between the heat-spreading lid and the protective layer.

20. The package structure as claimed in claim 16, wherein the substrate extends across opposite edges of the protective layer.
